(19) United States
(12) Patent Application Publication
(10) Pub. No.: US 2012/0292588 A1
(43) Pub. Date: Nov. 22, 2012

(54) NONVOLATILE MEMORY DEVICE

(76) Inventors: Satoru Fujii, Osaka (JP); Haruyuki Sorada, Okayama (JP); Takumi Mikawa, Shiga (JP)

(21) Appl. No.: 13/503,770

(22) PCT Filed: Dec. 15, 2011
(86) PCT No.: PCT/JP2011/007004

§ 371 Date: Apr. 24, 2012

(30) Foreign Application Priority Data
Dec. 15, 2010 (JP) 2010-279424

(51) Int. Cl. H01L 47/00

(52) U.S. Cl. 257/4; 257/E47.001

(57) ABSTRACT

A nonvolatile memory device including: a strip-shaped first electrode line (151); a third interlayer insulating layer (16); a variable resistance layer having a stacked structure including a first variable resistance layer (18a) comprising an oxygen-deficient transition metal oxide and formed in a memory cell hole (29) to cover a bottom and a side face, and a second variable resistance layer (18b) comprising an oxygen- and/or nitrogen-deficient transition metal oxynitride having a different oxygen content than the first variable resistance layer; a first electrode (19) formed in the memory cell hole; and a strip-shaped first line (22) formed in a direction crossing the first electrode line (151) to cover at least an opening of the memory cell hole, and z>(x+y) is satisfied when the transition metal is represented by M and compositions of the first and the second variable resistance layers by MO_{z} and MOₓN_{y}, respectively.

### TECHNICAL FIELD

The present invention relates to nonvolatile memory devices using variable resistance elements. More specifically, the present invention relates to a nonvolatile memory device in which a plurality of variable resistance layers having different oxygen content atomic percentages are formed in a memory cell hole to achieve miniaturization of elements, and diffusion of oxygen atoms between the variable resistance layers is prevented.

### BACKGROUND ART

With the progress of the digital technology of electronic devices in recent years, nonvolatile memory devices with a large capacity have been actively developed for storing data such as music, images, and information. For example, a nonvolatile memory device which uses ferroelectrics as a capacity element has already been used in many fields. In addition to the nonvolatile memory device which uses such a ferroelectric capacitor, a nonvolatile memory device (hereinafter referred to as a Resistive RAM or ReRAM) formed by using a material whose resistance value changes in response to an electric pulse application and which holds the state has been attracting attention in that it is easy to ensure consistency with a general semiconductor processing.

Patent Literature (PTL) 1 proposes, in an attempt to provide a smaller memory element and a memory device of larger capacity, a cross point ReRAM in which a variable resistance layer is formed in each of minute holes that are arranged in a matrix.

As for processes for forming embedded films in minute holes, a Chemical Vapor Deposition method (CVD method), an Atomic Layer Deposition method (ALD method), and the like have been developed. According to the ALD method, a film is grown in an atomic monolayer-by-atomic monolayer manner. This allows for conformal film growth even in a minute hole having a high aspect ratio.

Non Patent Literatures (NPLs) 1 and 2 report that a TiO₂ film and an HfO₂ film formed by the ALD method show a resistance changing phenomenon with an application of an electric pulse.

With the ALD method, a dense film that has a small thickness and fewer defects can be formed, which leads to a low leakage current. Thus, with an expectation to improve variable resistance characteristics, PTL 2 proposes a variable resistance nonvolatile memory element which uses a NiO thin film formed with the ALD method.

Furthermore, PTL 3 discloses a variable resistance element which includes two variable resistance layers having different oxygen content atomic percentages.

Further, PTL 4 discloses a variable resistance element which uses oxygen- and/or nitrogen-deficient tantalum oxynitride for a variable resistance element. PTL 4 is characterized in that the oxygen content atomic percentage to nitrogen included in an oxygen- and/or nitrogen-deficient tantalum oxynitride layer is in a range from 1.08 to 1.35, inclusive.

### CITATION LIST

Patent Literature
[PTL 1]
International Publication No. 2008/47711
[PTL 2]
Japanese Unexamined Patent Application Publication No. 2007-84935
[PTL 3]
International Publication No. 2008/149484
[PTL 4]
International Publication No. 2008/146461

Non Patent Literature
[NPL 1]
Journal Of Applied Physics, Vol. 98, 2005, p. 033715
[NPL 2]
Japanese Journal Of Applied Physics, Vol. 46 No. 4B, 2007, pp. 2172-2174

### SUMMARY OF INVENTION

### Technical Problem

However, when a nonvolatile memory device is formed with variable resistance layers disclosed by PTL 3, the following problems occur. In manufacturing processes of the nonvolatile memory device, heat treatment is performed on a variable resistance element in steps such as formation of an interlayer insulating film, formation of a plug, formation of a line, and a recovery annealing, when forming lines in multi-layers. The heat treatment in such steps cause oxygen diffusion in the variable resistance layers of the variable resistance element, from a second tantalum oxide layer having a high oxygen concentration, to a first tantalum oxide layer having a low oxygen concentration. This results in a deterioration of an oxygen concentration profile.

Further, different from a standard stacked structure, when two variable resistance layers having different oxygen content atomic percentages are embedded in a hole, the two variable resistance layers having different oxygen content atomic percentages contact not only at the bottom of a hole immediately above a lower electrode film but also on a side wall of the hole, that is, the two variable resistance layers are formed in a closed-end cylindrical shape. This significantly increases an area of an interface, causing a problem that an interdiffusion of oxygen atoms is more likely to occur.

The present invention has been conceived to solve the aforementioned conventional problems and to provide a nonvolatile memory device in which interdiffusion between a first variable resistance layer and a second variable resistance layer can be suppressed and a stable operation of a memory device is achieved.

### Solution to Problem

A nonvolatile memory device according to an aspect of the present invention includes: first electrode lines each of which is formed in a strip shape above a substrate; an interlayer insulating layer formed on the first electrode line and above the substrate; a memory cell hole which penetrates through the interlayer insulating layer to reach the first electrode line; a variable resistance layer formed in the memory cell hole so as to cover a bottom and a side face of the memory cell hole; a first electrode formed on the variable resistance layer in the memory cell hole; and first lines each of which is formed above the first electrode and the interlayer insulating layer so as to cover at least an opening of the memory cell hole, the first line being formed in a strip shape in a direction crossing the first electrode line, wherein the variable resistance layer has a stacked structure including (i) a first variable resistance layer comprising an oxygen-deficient transition metal oxide and (ii) a second variable resistance layer comprising an oxygen- and/or nitrogen-deficient transition metal oxynitride having an oxygen content atomic percentage different from an oxygen content atomic percentage of the first variable resistance layer, and z>(x+y) is satisfied when the transition metal is represented by M, a composition of the first variable resistance layer is represented by MO_{z}, and a composition of the second variable resistance layer is represented by MOₓN_{y}.

### Advantageous Effects of Invention

A nonvolatile memory device according to an implementation of the present invention makes it possible to suppress, regardless of an increase of interface portion between two variable resistance layers due to a structure in which the two variable resistance layers having different oxygen content atomic percentages are embedded in a hole, an interdiffusion between a metal oxide that is a first variable resistance layer and a second variable resistance layer because the second variable resistance layer comprises oxygen- and/or nitrogen-deficient metal oxynitride, and produces advantageous effects of stabilizing an operation of a memory device.

### BRIEF DESCRIPTION OF DRAWINGS

FIG. 1 shows a plan view of an example of a structure of a nonvolatile memory device according to Embodiment 1 of the present invention and its cross-sectional view taken along the line 1A-1A.

FIG. 2 shows a plan view of an example of a structure of a variable resistance element, which is a main part of FIG. 1, and its cross-sectional view taken along the line 2A-2A.

FIG. 3 is a cross-sectional view showing a step of manufacturing the nonvolatile memory device according to Embodiment 1 of the present invention.

FIG. 4 shows a plan view of a step of manufacturing the nonvolatile memory device according to Embodiment 1 of the present invention, and its cross-sectional view taken along the line 3A-3A.

FIG. 5 is a cross-sectional view showing a step of manufacturing the nonvolatile memory device according to Embodiment 1 of the present invention.

FIG. 6 is a cross-sectional view showing a step of manufacturing the nonvolatile memory device according to Embodiment 1 of the present invention.

FIG. 7 is a cross-sectional view showing a step of manufacturing the nonvolatile memory device according to Embodiment 1 of the present invention.

FIG. 8 shows a plan view and a cross-sectional view showing a step of manufacturing the nonvolatile memory device according to Embodiment 1 of the present invention.

FIG. 9 shows a plan view and a cross-sectional view showing a step of manufacturing the nonvolatile memory device according to Embodiment 1 of the present invention.

FIG. 10 is a graph showing a relation between a (O+N) proportion in a TaOₓN_{y} film and a specific electrical resistance.

FIG. 11 is a cross-sectional view of a planar-type element on which variable resistance characteristics was measured.

FIG. 12 is a graph showing variable resistance characteristics of the planar-type element when pulses are applied.

FIG. 13 is a graph showing variable resistance characteristics of the planar-type element when pulses are applied.

FIG. 14 is a graph showing variable resistance characteristics of the planar-type element when pulses are applied.

FIG. 15 is a cross-sectional view showing an example of a structure of a nonvolatile memory device according to Embodiment 2 of the present invention.

FIG. 16 is a cross-sectional view showing an example of a structure of a variable resistance element according to a modification of Embodiment 2 of the present invention.

FIG. 17 is a cross-sectional view showing an example of a structure of a nonvolatile memory device according to Embodiment 3 of the present invention.

FIG. 18 shows a plan view for describing an area of an interface portion between a plurality of variable resistance layers in the planar-type element and its cross-sectional view taken along the line A-A′.

FIG. 19 shows a plan view for describing an area of an interface portion of a plurality of variable resistance layers in a hole-type element, and its cross-sectional view taken along the line B-B′.

### DESCRIPTION OF EMBODIMENTS

A nonvolatile memory device according to an aspect of the present invention includes: first electrode lines each of which is formed in a strip shape above a substrate; an interlayer insulating layer formed on the first electrode line and above the substrate; a memory cell hole which penetrates through the interlayer insulating layer to reach the first electrode line; a variable resistance layer formed in the memory cell hole so as to cover a bottom and a side face of the memory cell hole; a first electrode formed on the variable resistance layer in the memory cell hole; and first lines each of which is formed above the first electrode and the interlayer insulating layer so as to cover at least an opening of the memory cell hole, the first line being formed in a strip shape in a direction crossing the first electrode line, wherein the variable resistance layer has a stacked structure including (i) a first variable resistance layer comprising an oxygen-deficient transition metal oxide and (ii) a second variable resistance layer comprising an oxygen- and/or nitrogen-deficient transition metal oxynitride having an oxygen content atomic percentage different from an oxygen content atomic percentage of the first variable resistance layer, and z>(x+y) is satisfied when the transition metal is represented by M, a composition of the first variable resistance layer is represented by MO_{z}, and a composition of the second variable resistance layer is represented by MOₓN_{y}.

Here, the first variable resistance layer may be in contact with the bottom and the side face of the memory cell hole, and the second variable resistance layer may be in contact with the first variable resistance layer.

It is preferable that the transition metal be a transition metal selected from the group consisting of tantalum, hafnium, zirconium, nickel, and titanium. Furthermore, it is preferable that the transition metal be tantalum.

It is preferable that a sum of the number of oxygen atoms and the number of nitrogen atoms in an oxygen- and/or nitrogen-deficient tantalum oxynitride be 50 to 70 atm %.

Furthermore, a structure in which a first current steering layer is disposed between the first electrode and the first line is also possible.

A miniaturized memory element can be realized through the following structures and manufacturing methods: (i) a method in which electrode layers and variable resistance layers to be required are stacked on a surface parallel to a substrate to form films, and then a processing is collectively performed using a dry etching process and (ii) a method in which minute holes are formed in advance, and variable resistance layers and electrodes are embedded in the minute holes.

According to the above-described method (i), a film forming process is easy. However, it is not easy to perform processing at a desired precision because dry etching is performed collectively on materials of thin films having different etching rates. In particular, the etching process is difficult to perform, when an element has a structure which includes a large number of stacked layers and when a size of an element is small.

On the other hand, according to the above-described method (ii), an etching process is not so much of a problem, but it is difficult to form variable resistance layers and electrodes in the minute holes. In general, with a film formation process using a physical technique such as a sputtering method, it is difficult to form in a minute hole having a high aspect ratio a film with good coverage. Therefore, the CVD method and the ALD method are used.

In a hole-type element that is formed by embedding in a minute hole variable resistance layers having different oxygen content atomic percentages, contact area between the variable resistance layers are larger than in a planar-type element which is formed by stacking, in the same footprint as the footprint of the hole-type element, variable resistance layers in parallel with the main surface of a substrate. For example, the planar-type element and the hole-type element that can be formed in square footprints each side of which is L nm are considered.

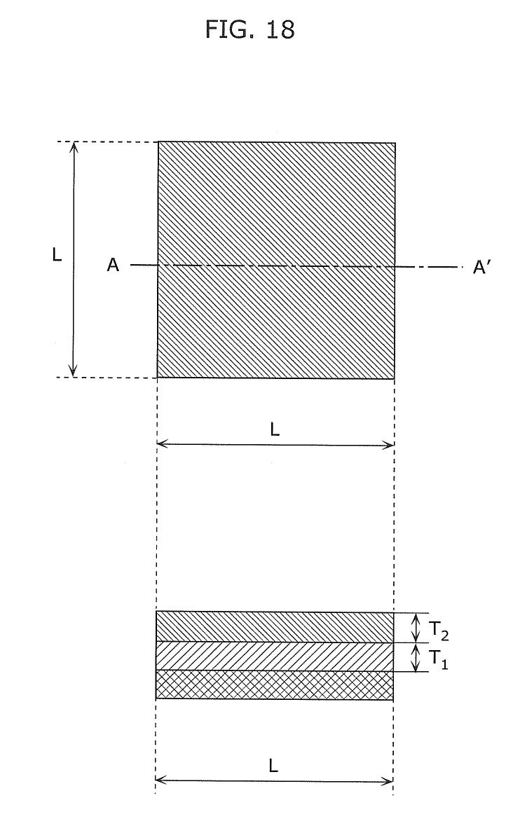

FIG. 18 shows a plan view schematically showing an example of the planar-type element and its cross-sectional view taken along the line A-A′. The contact area S between the variable resistance layers in such a planar-type element is represented by (Expression 1).

S=L² (Expression 1)

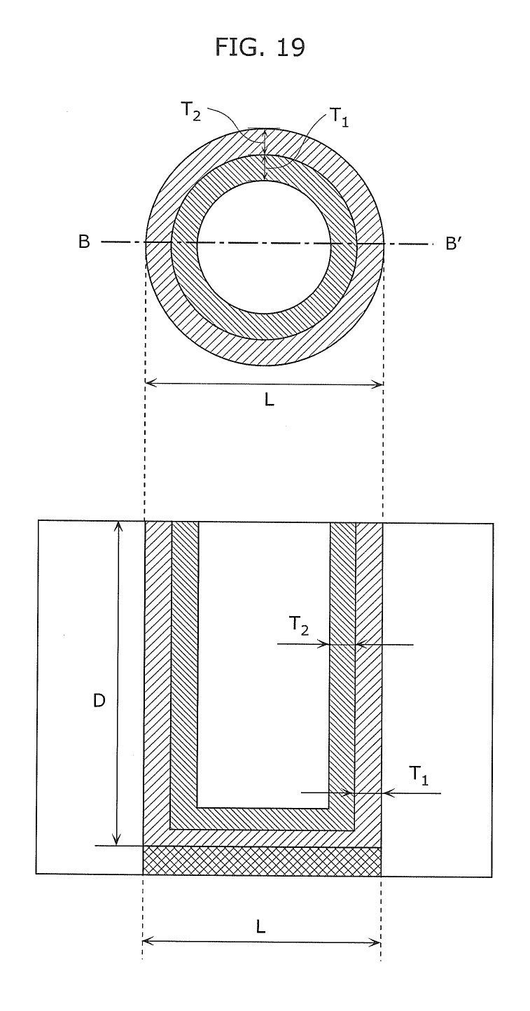

FIG. 19 shows a plan view schematically showing an example of the hole-type element and its cross-sectional view taken along the line B-B′. The contact area S between the variable resistance layers in such a hole-type element is represented by (Expression 2), wherein D denotes the depth of a hole, T₁ denotes the thickness of a first variable resistance layer, and T₂ denotes the thickness of a second variable resistance layer.

S=(L−2T₁)×(D−T₁)π+{(L−2T₁)/2}²π (Expression 2)

For example, when it is assumed that L=60 nm, D=120 nm, and T₁=T₂=10 nm, the contact area S between the variable resistance layers in the planar-type element is obtained using Expression 1 as 3600 nm². On the other hand, the contact area S between the variable resistance layers in the hole-type element is obtained using Expression 2 as 15079.6 nm², which is about 4.2 times the contact area of the planar-type stacked structure. Thus, it is assumed that the amount of interdiffusion of oxygen atoms between variable resistance layers increases.

Metal oxynitride of tantalum (Ta), titanium (Ti), and the like are stable compounds and have high barrier properties like tantalum nitride (TaN) and titanium nitride (TiN). Furthermore, in the metal oxynitride, it is considered that a portion of nitrogen atoms in metal nitride is substituted by oxygen atoms. Due to this, it is considered that sites where nitrogen is substituted by oxygen after diffusion are restricted and thus the diffusion of the oxygen atoms from the interface is suppressed.

Therefore, it is considered that with regard to the diffusion of oxygen atoms from the interface, there is an effect of suppressing sites where nitrogen is substituted by oxygen after diffusion, and thus the diffusion of oxygen atoms can be prevented. Thus, with the structure of the nonvolatile memory device according to an implementation of the present invention, although the area of the interface portion between two variable resistance layers increases due to the structure in which two variable resistance layers having different oxygen content atomic percentages are embedded in a hole, occurrence of interdiffusion between the second variable resistance layer and a metal oxide that is a first variable resistance layer can be suppressed because the second variable resistance layer is an oxygen- and/or nitrogen-deficient metal oxynitride.

Furthermore,

z>(x+y) (Expression 3)

is satisfied when a composition of the first variable resistance layer is represented by MO_{z}, and a composition of the second variable resistance layer is represented by MOₓN_{y}. When the relationship of Expression 3 is satisfied, the resistivity of a tantalum oxide layer that is the first variable resistance layer is higher than the resistivity of an oxygen- and/or nitrogen-deficient tantalum oxynitride layer.

A voltage pulse applied for a resistance change operation is distributed to both the tantalum oxide layer that is the first variable resistance layer and the oxygen- and/or nitrogen-deficient tantalum oxynitride layer that is the second variable resistance layer. The resistance change operation is caused by the component which is distributed to the tantalum oxide layer to which oxygen atoms enter and from which oxygen atoms exit. The voltage pulse component distributed to the tantalum oxide layer increases by setting the resistivity of the tantalum oxide layer to be higher than the resistivity of the oxygen- and/or nitrogen-deficient tantalum oxide layer. This makes it possible to operate the nonvolatile memory device at a low voltage.

Furthermore, when the relationship of Expression 3 is satisfied, the resistivity of the MO_{z} layer that is the first variable resistance layer is higher than the resistivity of the MOₓN_{y} layer that is the second variable resistance layer. The voltage pulse applied for the resistance change operation is applied to both the first variable resistance layer and the second variable resistance layer. The resistance change operation is caused by the voltage applied to the first variable resistance layer to which oxygen atoms enter and from which oxygen atoms exit. The component of the voltage pulse distributed to the first variable resistance layer becomes greater than the component of the voltage pulse distributed to the second variable resistance layer, by setting the resistivity of the first variable resistance layer to be higher than the resistivity of the second variable resistance layer. With this, the nonvolatile memory device can be operated at a lower voltage than the case where the variable resistance layer is made up of a single layer. The nonvolatile memory device having the above-described structure requires 2.4 V or less to cause the resistance change operation in the nonvolatile memory device, and can be operated at a low voltage.

The following describes embodiments according to the present invention with reference to the drawings. It is to be noted that the same reference numerals are assigned to the same components and descriptions thereof may be omitted. In addition, shapes of a transistor, a memory unit, and the like are schematically illustrated, and the number and the like of each of the components are examples which allow the illustration to be simple.

### Embodiment 1

[Device Structure]

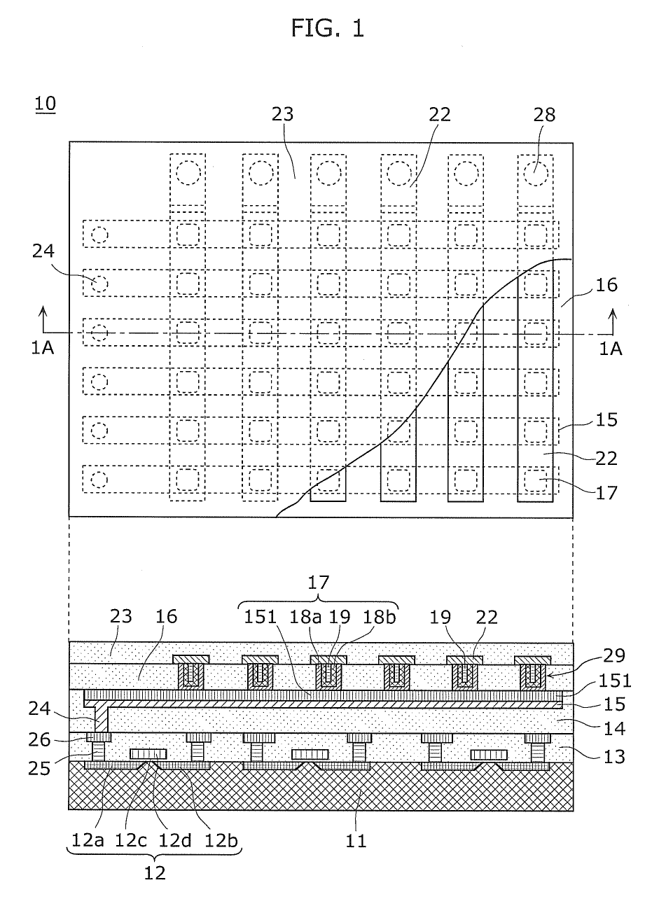

FIG. 1 shows a plan view schematically showing an example of a structure of a nonvolatile memory device 10 according to Embodiment 1 of the present invention, and its cross-sectional view showing in a direction of arrows a cross-section taken along the line 1A-1A. The plan view in FIG. 1 shows a hypothetical state in which a portion of a fourth interlayer insulating layer 23 that is the topmost layer is removed for the ease of understanding.

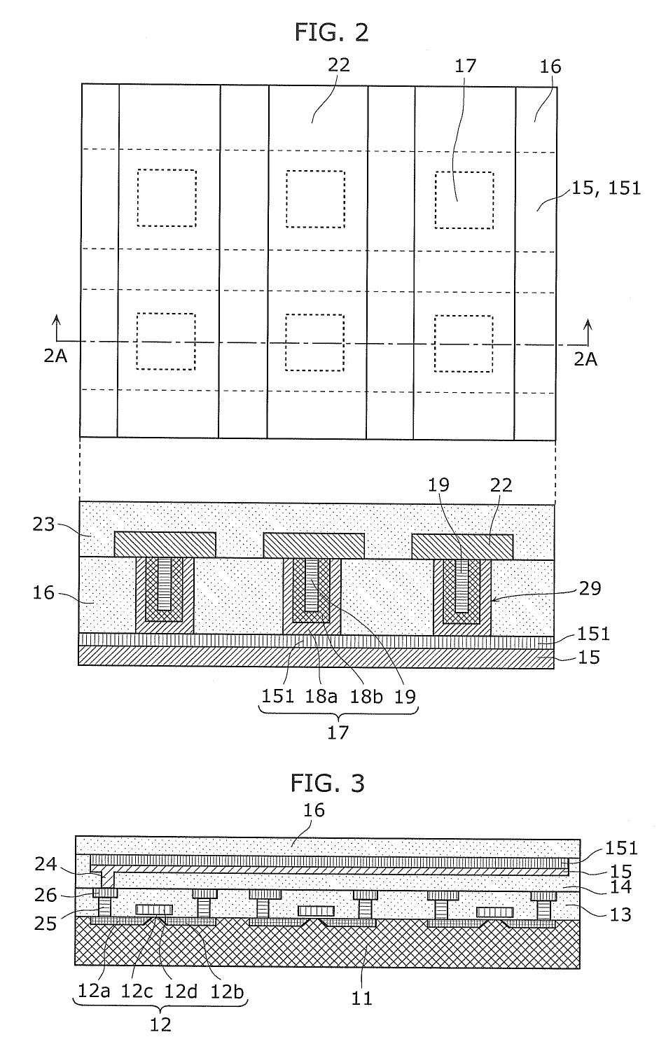

FIG. 2 shows a plan view of a first variable resistance element 17, which is a main part of FIG. 1, and its cross-sectional view showing in a direction of arrows a cross-section taken along the line 2A-2A.

A nonvolatile memory device 10 according to this embodiment includes: a substrate 11; a lower layer line formed of a first lining 15 formed above a substrate 11, and a first electrode line 151 formed on the first lining 15 so as to be physically in contact with the first lining 15; and a third interlayer insulating layer 16 formed so as to cover the lower layer line. The lower layer line is formed in a strip shape viewed from a direction perpendicular to the main surface of the substrate 11 (substrate-thickness direction, hereinafter).

In the third interlayer insulating layer 16, memory cell holes 29 that reach the first electrode line 151 are formed at a predetermined interval. The first variable resistance element 17 is formed for each of the memory cell holes 29.

Here, each of the first electrode lines 151 is a strip-shaped electrode, and forms a first electrode of the first variable resistance element 17. Each of the first linings 15 is in substantially the same shape as the first electrode line 151 and comprises a material having lower resistance than the first electrode line 151, so as to reduce line resistance of the first electrode line 151 that is the strip-shaped electrode.

In the memory cell hole 29, there are: a first variable resistance layer 18a formed in a conformal manner substantially in a uniform thickness according to the shape of the memory cell hole 29 so as to cover the bottom and the side wall of the memory cell hole 29 and be in physical contact with the first electrode line 151; a second variable resistance layer 18b formed so as to cover the bottom and the side wall of the first variable resistance layer 18a and be in physical contact with the first variable resistance layer 18a; and a first electrode 19 formed inside of the second variable resistance layer 18b so as to be in physical contact with the second variable resistance layer 18b. Here, conformal means high shape adaptivity, and it is defined that the first variable resistance layer 18a can be formed at the bottom and on the side wall inside the memory cell hole 29 in substantially a uniform thickness without a gap and disconnection due to a step.

For each of memory cell holes 29, the first variable resistance element 17 is formed of (i) the first electrode line 151 exposed at the bottom of the memory cell hole 29, (ii) the first variable resistance layer 18a inside the memory cell hole 29, (iii) the second variable resistance layer 18b inside the memory cell hole 29; and (iv) the first electrode 19 inside the memory cell hole 29.

The first variable resistance layer 18a preferably comprises a transition metal oxide, and more preferably comprises an oxygen-deficient tantalum oxide. The second variable resistance layer 18b preferably comprises an oxygen- and/or nitrogen-deficient metal oxynitride, and more preferably comprises an oxygen- and/or nitrogen-deficient tantalum oxynitride.

Here, when an oxide of a transition metal M is represented by MOₓ (x is a composition ratio expressed in the number of moles of oxygen O, when it is assumed that the transition metal M is 1 mol), an oxygen-deficient transition metal oxide is an oxide having a composition ratio x of oxygen O smaller than the composition ratio with which a stoichiometrically stable state is achieved (when the transition metal M is tantalum Ta, 2.5).

Furthermore, when an oxynitride of a transition metal M is represented by MOₓN_{y} (x and y are composition ratios expressed in the number of moles of oxygen O and nitrogen N, respectively, when it is assumed that the transition metal M is 1 mol), the oxygen- and/or nitrogen-deficient metal oxynitride is an oxide having a sum of a composition ratio x of oxygen O and a composition ratio y of nitrogen N smaller than the sum of composition ratios with which a stoichiometrically stable state is achieved (when the transition metal M is tantalum Ta, 2.5).

For example, the oxygen- and/or nitrogen-deficient tantalum oxynitride is defined as follows. In general, it is stable for tantalum to be +5 valence ion, oxygen to be −2 valence ion, and nitrogen to be −3 valence ion. Accordingly, the oxygen- and/or nitrogen-deficient tantalum oxynitride which satisfies 2x+3y=5 can exist stably, when a composition of the oxygen- and/or nitrogen-deficient tantalum oxynitride is represented by TaOₓN_{y}. The oxygen- and/or nitrogen-deficient tantalum oxynitride is an oxygen- and/or nitrogen-deficient tantalum oxynitride having a composition that satisfies 2x′+3y′<5, when the composition of the oxygen- and/or nitrogen-deficient tantalum oxynitride is represented by TaO_{x′}N_{y′}.

With a variable resistance layer comprising a transition metal oxide formed of the oxygen-deficient tantalum oxide, it is possible to obtain the nonvolatile memory element that uses variable resistance phenomenon and having reversible and stable rewriting characteristics. This is described in detail in PTL 5: International Publication No. 2008/059701.

Furthermore, diffusion of oxygen atoms is less likely to occur with the oxygen- and/or nitrogen-deficient tantalum oxynitride layer than with the first tantalum oxide layer described in PTL 3: International Publication No. 2008/149484. This is because a metal oxynitride of Ta is a stable compound and has high barrier properties like TaN. Furthermore, in the metal oxynitride, it is considered that a portion of nitrogen atoms in metal nitride is substituted by oxygen atoms. Due to this, it is considered that sites where nitrogen is substituted by oxygen after diffusion are restricted and thus the diffusion of the oxygen atoms from the interface is suppressed.

Accordingly, diffusion of oxygen atoms out of the tantalum oxide layer can be suppressed. Thus, the deterioration in oxygen concentration profile due to the increase in interface layer area, which is a problem associated with the hole-type variable resistance element, can be reduced.

The first variable resistance layer 18a and the second variable resistance layer 18b are not limited to the tantalum oxide and the tantalum oxynitride, respectively, but may comprise an oxide and oxynitride, respectively, of which base is a transition metal such as titanium (Ti), hafnium (Hf), zirconium (Zr), nickel (Ni), or the like. These transition metal oxides shows a specific resistance value when a voltage or a current equal to or larger than a threshold is applied and maintains the resistance value until the next application of a pulse voltage or a pulse current of a certain value and thus can be used in the nonvolatile memory element.

It is preferable that an oxygen content atomic percentage of the first variable resistance layer 18a be higher than an oxygen content atomic percentage of the second variable resistance layer 18b. In other words, it is preferable that

z>(x+y) (Expression 4)

be satisfied, when the transition metal oxide comprised in the first variable resistance layer 18a is represented by MO_{z}, and the transition metal oxynitride comprised in the second variable resistance layer 18b is represented by MOₓN_{y}. Here, in particular, x>0 and y>0 may be satisfied. The variable resistance element of which variable resistance layer is made up of two variable resistance layers having different oxygen content atomic percentages is described in detail in PTL 3: International Publication No. 2008/149484.

It is possible to promote the resistance changing phenomenon with the oxidation-reduction reaction at the interface between the first electrode line 151 and the variable resistance layer, by setting the oxygen content atomic percentage of the variable resistance layer high in the vicinity of the first electrode line 151. With this, it is possible to obtain good memory cell characteristics that can be operated at low voltage.

It is preferable that the first electrode line 151 comprise platinum, iridium, palladium, and the like. The standard electrode potential of platinum and iridium is +1.2 eV, and the standard electrode potential of palladium is +1.0 eV. In general, the standard electrode potential is an index that indicates susceptibility to oxidation. A large value indicates that the oxidation is less likely to occur, and a small value indicates that the oxidation is more likely to occur.

The research conducted by the inventors shows that the resistance change is more and more likely to occur as the difference between the standard electrode potential of a material comprised in the electrode and the standard electrode potential of the transition metal included in the variable resistance layer is larger, and the resistance change is less and less likely to occur as the difference is smaller. Based on the above finding, it is assumed that the susceptibility of the materials of the electrode and the variable resistance layer to oxidation has much to do with a mechanism of a resistance changing phenomenon.

Tantalum has a standard electrode potential of −0.6 eV, which is lower than the standard electrode potential of platinum, iridium, and palladium. Thus, at the interface between (i) the first electrode line 151 comprising platinum, iridium, and palladium and (ii) the first variable resistance layer 18a comprising the tantalum oxide, the oxidation-reduction reaction occurs, oxygen atoms are transferred, and the resistance changing phenomenon occurs in the above-described preferable structure.

The first lining 15 may be formed of, for example, Ti—Al—N alloy, Cu, Al, or Ti—Al alloy, or a stacked structure thereof. The first electrode line 151 can comprise Pt, Ir, or the like. The first lining 15 and the first electrode line 151 can be formed easily by forming a film with a sputtering method, and then performing an exposure process and an etching process.

It is preferable that the first electrode 19 comprise a material having a standard electrode potential lower than the material comprised in the first electrode line 151. Further, it is preferable that the first electrode 19 comprise a material having a lower standard electrode potential than the transition metal comprised in the variable resistance layer. With such a structure, oxidation-reduction reaction of the first variable resistance layer 18a occurs selectively in the vicinity of the interface between the first electrode line 151 and the first variable resistance layer 18a, and a stable resistance change can be achieved.

The first electrode 19 may comprise a nitride of the transition metal comprised in the first variable resistance layer 18a and the second variable resistance layer 18b. For example, when the first variable resistance layer 18a and the second variable resistance layer 18b comprise the tantalum oxide, the first electrode 19 may comprise tantalum nitride (TaN), and aluminum.

The first variable resistance layer 18a, the second variable resistance layer 18b, and the first electrode 19 are exposed at the upper opening of the memory cell hole 29, and a first line 22 is formed so as to cover the upper opening. The first line 22 is formed in a surface which is parallel to the main surface of the substrate and is different from the surface on which the first lining 15 is disposed. Each of the first lines 22 is (i) in a strip shape in the direction crossing the first lining 15, (ii) larger in shape (area) than the opening of the memory cell hole 29, and (iii) formed on the third interlayer insulating layer 16 so as to completely cover and extend beyond the opening of the memory cell hole 29.

The first line 22 may comprise a material having a low resistance, such as copper (Cu), and aluminum (Al).

As shown in FIG. 1, the first lines 22 extend to an outside of a region in which the first variable resistance elements 17 are arranged in a matrix. In the matrix region, the first line 22 serves as a line (a word line, a bit line, or the like) that connects memory cells.

In this embodiment, a silicon single-crystal substrate is used as the substrate 11. A semiconductor circuit in which an active element 12 such as a transistor is integrated is provided on the substrate 11. In FIG. 1, the active element 12 shows a transistor (MOS-FET) that is made up of: a source region 12a, a drain region 12b, a gate insulating film 12c, and a gate electrode 12d. Note that elements that are generally necessary for a memory circuit such as a DRAM may also be formed on the substrate 11 besides the active element 12.

In a region different from the matrix region in which the first variable resistance elements 17 are formed (e.g., a periphery of the matrix region) viewed from the thickness direction of the substrate 11, the first lining 15 and the first line 22 are connected to the active element 12.

In other words, in FIG. 1, the first lining 15 is connected to the source region 12a of the active element 12 through a second embedded conductor 24 and a first embedded conductor 25 that are embedded in memory cell holes formed in a second interlayer insulating layer 14 and a first interlayer insulating layer 13, respectively, and a circuit line 26. Note that the first line 22 is connected to another active element (not shown) in a similar manner through a third embedded conductor 28. The active element 12 may be disposed below the matrix region.

The first interlayer insulating layer 13, the second interlayer insulating layer 14, the third interlayer insulating layer 16, and the fourth interlayer insulating layer 23 can comprise insulating oxide or nitride. Specifically, a silicon oxide (SiO) formed by the CVD method, a TEOS-SiO film formed by the CVD method using ozone (O₃) and tetraethoxysilane (TEOS), a silicon nitride (SiN) film, or the like may be used. It is preferable that the first interlayer insulating layer 13 and the second interlayer insulating layer 14 comprise a fluoride-containing oxide (e.g., SiOF) and a carbon-containing nitride (e.g., SiCN), or an organic resin (e.g., polyimide) so as to reduce a parasitic capacitance between the lines. For the third interlayer insulating layer 16, a silicon carbon nitride film (SiCN) film, a silicon oxycarbide (SiOC) film, or a silicon fluorine oxide (SiOF) film that are low dielectric constant materials may be used.

The circuit line 26 may be formed of aluminum according to a conventional technique. However, it is preferable that the circuit line 26 be formed of copper so that low resistance can be achieved even when miniaturized.

[Manufacturing Method]

Next, a manufacturing method of the nonvolatile memory device according to Embodiment 1 of the present invention is described using the example of the above-described nonvolatile memory device 10.

FIG. 3 is a cross-sectional view of the nonvolatile memory device 10 after steps of forming, on the substrate 11 on which the active element 12 is formed, the second interlayer insulating layer 14, the first lining 15, the first electrode line 151, and the third interlayer insulating layer 16.

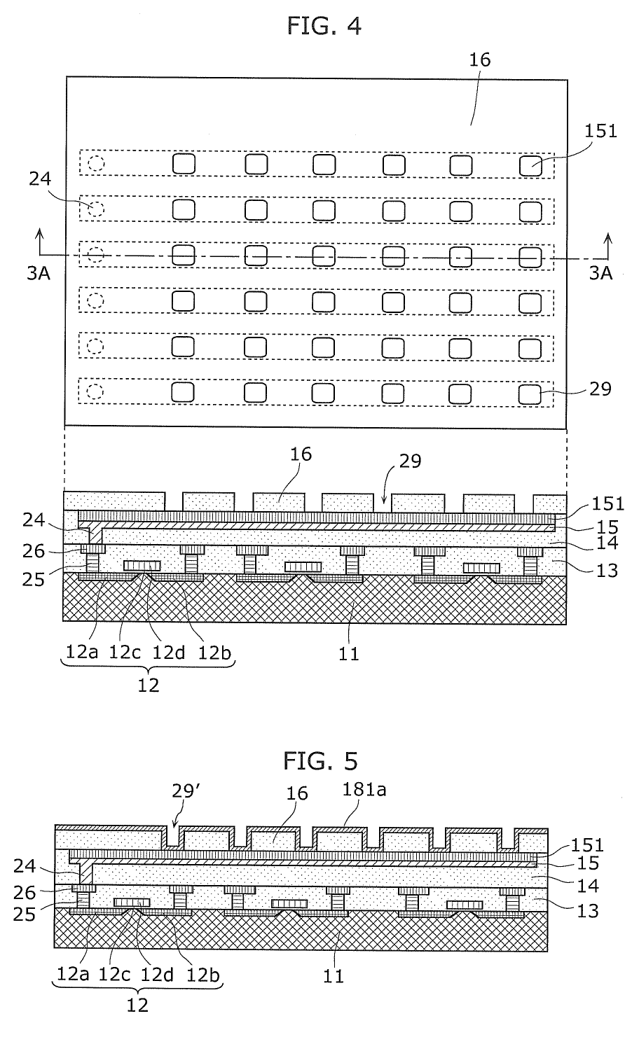

FIG. 4 shows a plan view of the nonvolatile memory device 10 after a step of forming the memory cell holes 29 in the third interlayer insulating layer 16, and its cross-sectional view showing in a direction of arrows a cross-section taken along the line 3A-3A. Note that, including the cross-sectional view shown in FIG. 4, each of the cross-sectional views shown in FIG. 4 to FIG. 9 is a cross-sectional view showing in a direction of arrows a cross-section taken along the line 3A-3A of the nonvolatile memory device 10 in each of the steps.

FIG. 5 is a cross-sectional view of the nonvolatile memory device 10 after a step of forming, in the memory cell holes 29 and on the third interlayer insulating layer 16, a first variable resistance material layer 181a that will be formed into the first variable resistance layer 18a.

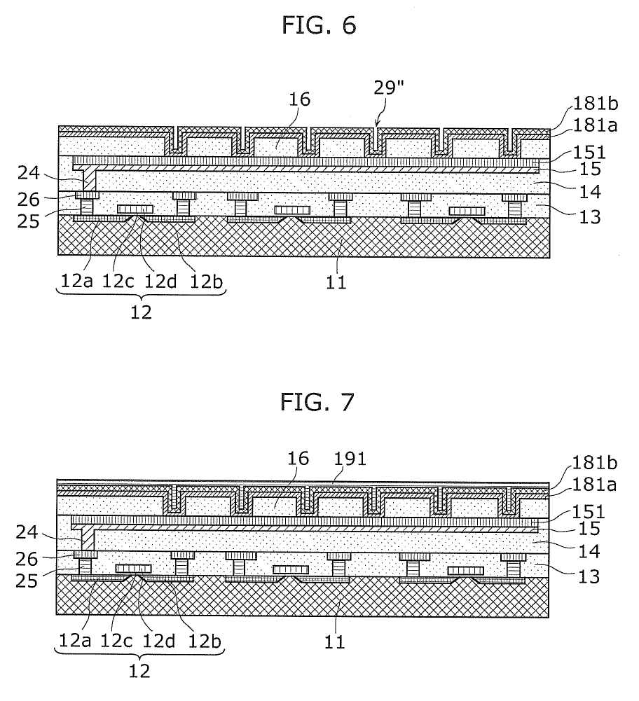

FIG. 6 is a cross-sectional view of the nonvolatile memory device 10 after a step of forming, on the first variable resistance material layer 181a, a second variable resistance material layer 181b that will be formed into the second variable resistance layer 18b.

FIG. 7 is a cross-sectional view of the nonvolatile memory device 10 after a step of forming, on the second variable resistance material layer 181b, a first electrode material layer 191 that will be formed into the first electrode 19.

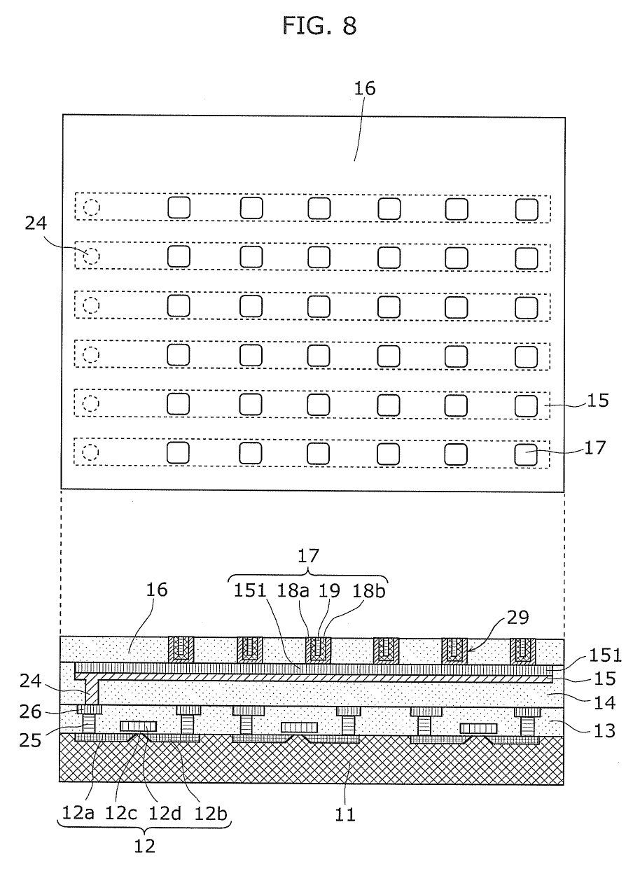

FIG. 8 shows a plan view and a cross-sectional view of the nonvolatile memory device 10 after a step of removing, except for the first variable resistance material layer 181a, the second variable resistance material layer 181b, and the first electrode material layer 191 that are formed in the memory cell holes 29, the remaining first variable resistance material layer 181a, the second variable resistance material layer 181b, and the first electrode material layer 191 by chemical mechanical polishing (CMP).

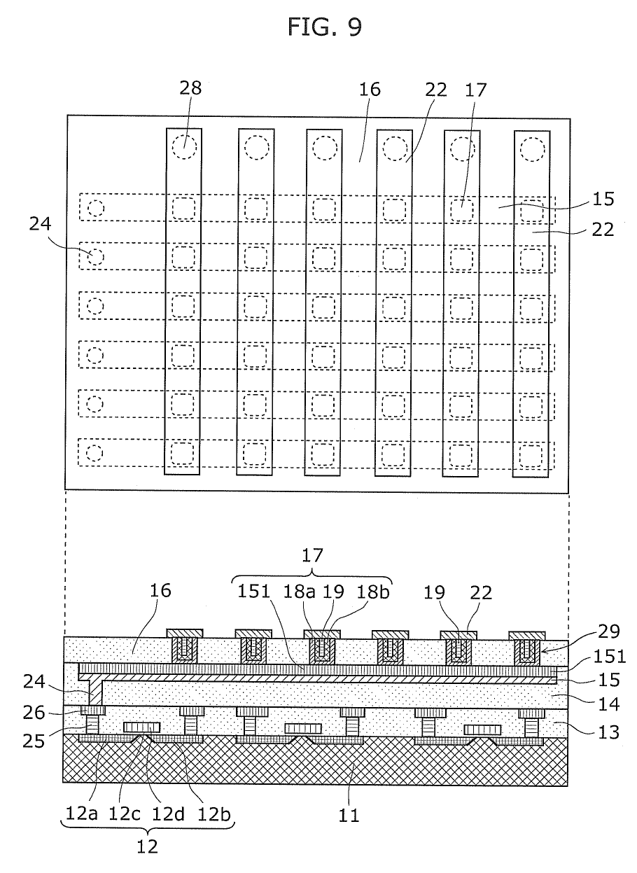

FIG. 9 shows a plan view and a cross-sectional view of the nonvolatile memory device 10 after a step of stacking the first line 22 in such a manner that the first line 22 completely covers and extends beyond the upper openings of the memory cell holes 29.

The following describes a method of manufacturing the nonvolatile memory device 10 according to this embodiment with reference to FIG. 3 to FIG. 9.

First, as shown in FIG. 3, a plurality of the active elements 12, the first interlayer insulating layer 13, the second interlayer insulating layer 14, the second embedded conductor 24, the first embedded conductor 25, the circuit line 26, the first lining 15, the first electrode line 151, and the third interlayer insulating layer 16 are formed on or above the substrate 11.

In particular, the first lining 15 and the first electrode line 151 may be embedded in the second interlayer insulating layer 14. Such structure can be formed, for example, as follows.

Specifically, grooves in which the first lining 15 and the first electrode line 151 are to be embedded, and a memory cell hole which is for connecting the first lining 15 and the first electrode line 151 to the circuit line 26 are formed in the second interlayer insulating layer 14 using a technique used in a general semiconductor processing. The grooves are formed in a strip shape viewed from a substrate-thickness direction.

After forming these grooves and the memory cell hole, conductors that will be formed into the first lining 15 and the first electrode line 151 are embedded using the CVD method and the like. Then, an unnecessary portion is removed by, for example, the CMP.

For other steps for forming the structure shown in FIG. 3, well-known manufacturing methods can be used. Thus, detailed descriptions thereof are omitted.

Next, as shown in FIG. 4, the memory cell holes 29 are formed at a constant arrangement pitch in the third interlayer insulating layer 16 that covers the first electrode line 151, in such a manner that the first electrode line 151 is exposed at the bottom of each of the memory cell holes 29. As the plan view in FIG. 4 shows, the size of the memory cell hole 29 is smaller than the width of the first lining 15. In the drawing, the memory cell hole 29 has a square shape. However, note that the memory cell hole 29 may have a circle shape, an oval shape, or any other shapes.

The memory cell hole 29 can be formed by a general semiconductor processing. Thus, a detailed description thereof is omitted.

Next, as shown in FIG. 5, the first variable resistance material layer 181a (first deposited film) that will be formed into the first variable resistance layer 18a is formed on the third interlayer insulating layer 16 in which the memory cell holes 29 are formed. In this embodiment, a tantalum oxide is deposited by the CVD method in the memory cell hole 29 (on the side wall and at the bottom) and on the third interlayer insulating layer 16 so as to form the first variable resistance material layer 181a.

In this embodiment, as an example, the CVD method is employed to form the first variable resistance material layer 181a. The first variable resistance material layer 181a may also be formed using other film formation methods such as the sputtering method and the ALD method which is especially suitable to form a conformal film in a minute hole. With this process, the first variable resistance material layer 181a is formed in the memory cell hole 29 (on the side wall and at the bottom) in a conformal manner in a substantially uniform thickness.

As a source gas, (Tert-Butylimido)Tris(Diethylamido)Tantalum ((CH₃)₃CNTa[N(C₂H₅)₂]₃, hereinafter described as TBTDET) shown in (chemical formula I) can be used.

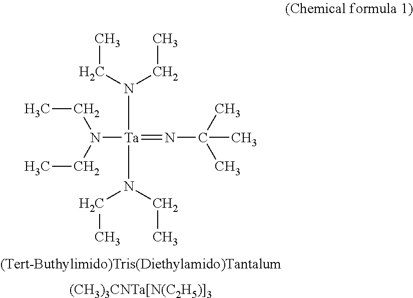

As a reactive gas, for example, ozone (O₃) gas is used. After the film is formed, nitrogen (N₂) gas is used as a purge gas. Note that the type of the gas is not limited to the above.

In a method of forming the first variable resistance material layer 181a according to this embodiment, first, a source vessel is filled with the TBTDET that is a source (precursor) of a variable resistance layer. A substrate, which is heated to a temperature at which self-decomposition reaction of the source gas occurs (e.g., 325 degrees Celsius), is held in a deposition chamber. It is to be noted that substrates are heated to multiple temperatures of 325 degrees Celsius, 350 degrees Celsius, 400 degrees Celsius, and 440 degrees Celsius in the experiment.

A source gas is produced by heating the TBTDET in the source vessel to 100 degrees Celsius and bubbling the TBTDET with the nitrogen gas that is a carrier gas. The source gas is introduced into the deposition chamber. Simultaneously, an O₃ gas generated as a reactive gas by an ozonizer is introduced into the deposition chamber. With this, the TBTDET is oxidized to form a Ta oxide layer, and ligands included in the TBTDET which are oxidized to by-products such as CO₂ are removed.

After the Ta oxide of a desired thickness is formed, a nitrogen gas is introduced into the chamber to purge the gas in the chamber so as to remove an excess reactive gas and by-products.

Next, as shown in FIG. 6, the second variable resistance material layer 181b (second deposited film) that will be formed into the second variable resistance layer 18b is formed on the first variable resistance material layer 181a that is formed on the side wall and at the bottom of the memory cell holes 29 and on the third interlayer insulating layer 16.

In this embodiment, the second variable resistance material layer 181b is formed, by depositing tantalum oxynitride by the CVD method, in the memory cell hole 29′ (on the side wall and at the bottom) in which the first variable resistance material layer 181a is formed and on the first variable resistance material layer 181a that is formed on the third interlayer insulating layer 16.

In this embodiment, as an example, an oxygen- and/or nitrogen-deficient metal oxynitride thin film that is the second variable resistance material layer 181b is formed using continuous processing that involves the CVD method and oxidization processing.

Specifically, for example, the method of forming the oxygen- and/or nitrogen-deficient metal oxynitride thin film includes: a first step of introducing (i) the source gas that includes atoms of a transition metal and (ii) the reactive gas; a second step of purging the source gas and the reactive gas after the first step; and a third step of introducing an oxidizing reactive gas such as O₃ and O₂ after the second step.

In the first step, first, a metal nitride thin film is formed using a nitriding reactive gas. Except that the type of reactive gas is different, conditions such as a film formation temperature is the same as with the formation of the first variable resistance material layer 181a. Thus, descriptions on the common portions in the method of formation are omitted.

In the third step, a substrate temperature is kept at the same temperature as the first step and the second step, e.g. 350 degrees Celsius, and oxidizing reactive gases such as O₃ and O₂ are introduced for a predetermined period of time to substitute the nitrogen atoms in the metal nitride thin film with oxygen atoms. The metal oxynitride thin film is thus formed.

Note that the composition of the metal oxynitride can be controlled by performing the above-described first step, the second step, and the third step not once but repeating more than once.

Considering the mechanism of formation of the layer, it is to be noted that it is assumed that oxide and oxynitride of which base metal is hafnium, zirconium, nickel, or titanium can be used as the transition metal oxide and the transition metal oxynitride comprised in the variable resistance layers to form the metal oxides having different oxygen content atomic percentages as with the tantalum oxide and tantalum oxynitride.

In this case, as a source (precursor) of the variable resistance layer, zirconium chloride [ZrCl₄], tetra(ethylmethylamino)hafnium[Hf(NCH₃C₂H₅)₄], nickel 1-dimethylamino-2-methyl-2-butanolate[Ni(C₇H₁₆NO)], tetraethoxytitanium[Ti(OC₃H₇)₄], and the like can be used.

Subsequently, as shown in FIG. 7, the first electrode material layer 191 is formed on the second variable resistance material layer 181b.

In this embodiment, the first electrode material layer 191 is formed by depositing, for example, by the ALD method and the CVD method, a tantalum nitride (TaN) in the memory cell hole 29″ (on the side wall and at the bottom) in which the second variable resistance material layer 181b is formed and on the second variable resistance material layer 181b that is formed on the first variable resistance material layer 181a that is formed on the third interlayer insulating layer 16.

The specific method of the CVD method is the same as the method applied to the first variable resistance material layer 181a or the second variable resistance material layer 181b. Thus, a detailed description thereof is omitted. As a source (precursor), TBTDET and TaCl₅, Ta(OC₂H₅)₅, and the like can be used. As a reactive gas, a nitriding gas can be used.

Next, as shown in FIG. 8, the CMP process is used to remove portions of the first electrode material layer 191, the second variable resistance material layer 181b, and the first variable resistance material layer 181a (i) which cover the surface of the third interlayer insulating layer 16 and (ii) above the upper opening of the memory cell hole 29 (a portion having a height from the substrate higher than the height of the upper surface of the third interlayer insulating layer 16). With this, the first variable resistance layer 18a, the second variable resistance layer 18b, and the first electrode 19 are embedded in the memory cell hole 29.

Next, as shown in FIG. 9, the first line 22 is formed so as to be connected to the first electrode 19. The first line 22 can be formed using a well-known technique. Thus, a detailed description thereof is omitted.

The first line 22 is formed on the third interlayer insulating layer 16. The first line 22 completely covers the memory cell holes 29, has a shape (area) that is at least larger than the opening of each of the memory cell holes 29 viewed from the substrate-thickness direction, and is formed in a strip shape in a direction crossing the first lining 15 and the first electrode line 151. The first lines 22 are formed so as to extend beyond the region in which the first variable resistance elements 17 are formed in a matrix. When forming the first line 22, the third embedded conductor 28 is also formed simultaneously. The first line 22 is connected to a circuit line (not shown) through the third embedded conductor 28 so as to be electrically connected to an active element provided in a position not shown in the drawing.

Furthermore, the fourth interlayer insulating layer 23 is formed so as to cover the third interlayer insulating layer 16 and the first line 22. Thus, the nonvolatile memory device shown in FIG. 1 and the like is obtained.

[Properties of an Oxygen- and/or Nitrogen-Deficient Tantalum Oxynitride Layer]

The following describes a relationship between specific electrical resistance and a composition of the oxygen- and/or nitrogen-deficient tantalum oxynitride thin film formed as the second variable resistance material layer 181b.

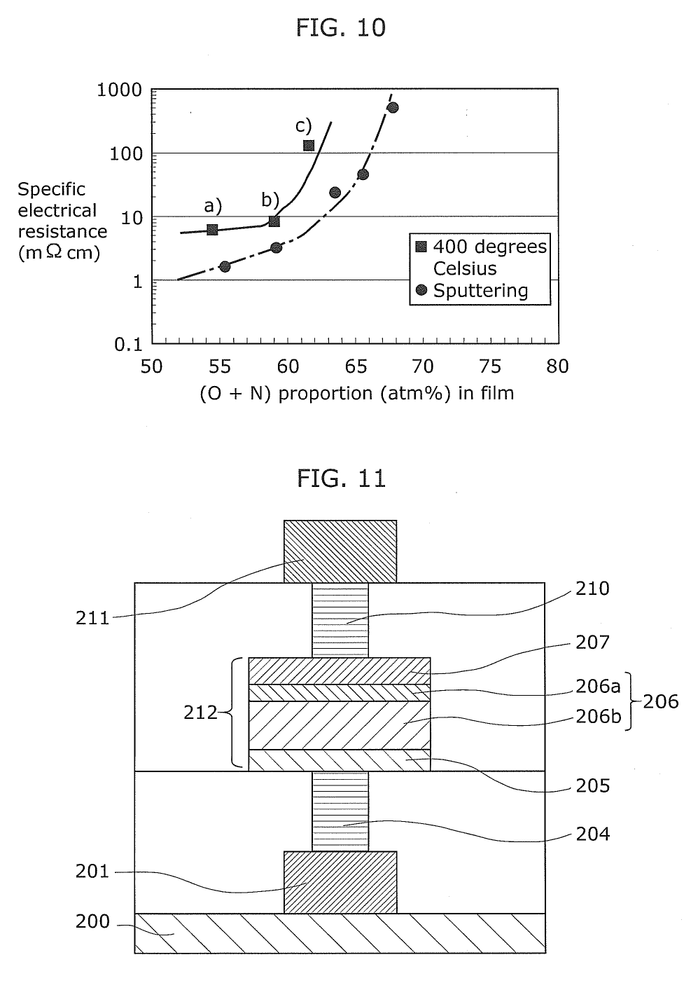

FIG. 10 shows a relationship between (i) an atomic percentage of O+N (sum of the number of oxygen atoms and the number of nitrogen atoms) in the oxygen- and/or nitrogen-deficient tantalum oxynitride thin film (residue C from the TBTDET is included) formed by the continuous processing that involves the CVD method and the oxidization processing and (ii) specific electrical resistance of the oxygen- and/or nitrogen-deficient tantalum oxynitride thin film. The composition is analyzed by Rutherford Backscattering Spectrometry (RBS). It is considered that the oxygen content in the oxygen- and/or nitrogen-deficient tantalum oxynitride thin film formed according to the above-described method depends on conditions of an oxidation processing (flow rate of oxidizing gas, time), which is performed after forming the film by the CVD method.

Note that the composition of the oxygen and the nitrogen analyzed by the RBS contains a relatively large error of ±4% in a unit of atomic percentage. This causes an error on the atm % of O+N as well. When the error due to the RBS is taken into account, the atm % of O+N is in a range from 50 to 70. Furthermore, in FIG. 10, a relationship between specific electrical resistance and the atm % of O in the tantalum oxide film formed by the sputtering method (i.e. corresponds to atm % of N=0) is also plotted as a comparison example.

FIG. 10 shows correlation between the film composition and the specific electrical resistance. The oxygen- and/or nitrogen-deficient tantalum oxynitride thin film formed by the CVD method and the tantalum oxide film formed by the sputtering method shows a similar tendency, that is, as the atm % of O+N increases, the specific electrical resistance value of the film increases.

The solid line in FIG. 10 indicates the specific electrical resistance, which is obtained by measuring using a four-terminal measurement technique a sheet resistance value of the tantalum oxynitride layer that is the second variable resistance layer formed so as to be 50 nm in thickness while keeping the substrate temperature at 400 degrees Celsius.

Here, the a) in the drawing indicates the specific electrical resistance of a sample of which composition is analyzed as Ta/O/N/C=33.6/0/54.5/11.9 (atm %) before the oxidization processing is performed after forming the film by the CVD method. Note that although the analysis result of atm % of O=0 is obtained before the oxidization processing is performed, it is unlikely that the sample has no O at all. Thus, the result is assumed to be an error due to a low analytical sensitivity on O less than 4 atm %.

The b) in the drawing indicates the specific electrical resistance of a sample of which composition is analyzed as Ta/O/N/C=32.4/4.7/54.3/8.6 (atm %) (represented as TaO_{0.15}N_{1.68}). The c) in the drawing indicates the specific electrical resistance of a sample of which composition is analyzed as Ta/O/N/C=29.9/7.4/54.2/8.5 (atm %) (represented as TaO_{0.25}N_{1.81}).

The specific electrical resistance of the tantalum oxide material layer indicated by the alternate long and short dashed line in FIG. 10 is calculated based on (i) the film thickness measured with a cross-sectional scanning electron microscopy (SEM) and X-ray fluorescence and (ii) a sheet resistance value measured using the four-terminal measurement technique.

Next, operation examples of the stacked structure, which includes the first variable resistance layer and the oxynitride layer that is the second variable resistance layer according to this embodiment, as a memory is verified. Specifically, operation examples for writing/reading data are verified using a planar-type element shown in FIG. 11.

The planar-type element for verification of properties is manufactured by stacking on a silicon substrate 200 on which a SiN film (100 nm in thickness) is formed: a lower electrode 205 formed of TaN, a second variable resistance layer 206b that is a TaOₓN_{y} film (30 nm in thickness) formed by the CVD method; a first variable resistance layer 206a that is a TaO_{z} film (5 nm in thickness) formed by the sputtering method; and an upper electrode 207 (50 nm in thickness) that is an Ir film formed by the sputtering method, in this order. The first variable resistance layer 206a and the second variable resistance layer 206b make up a variable resistance layer 206. The lower electrode 205 and the upper electrode 207 are connected to lines 201 and 211 through contact plugs 204 and 210, respectively.

According to the above-described method, following elements are manufactured: an element A that is formed while the substrate is kept at 325 degrees Celsius and includes a TaOₓN_{y} film of which composition is analyzed as x=0.31, y=1.41; an element B that is formed while the substrate is kept at 400 degrees Celsius and includes a TaOₓN_{y} film (corresponds to the sample b) in FIG. 10) of which composition is analyzed as x=0.15, y=1.68; and an element C that is formed while the substrate is kept at 400 degrees Celsius and includes a TaOₓN_{y} film (corresponds to the sample c) in FIG. 10) of which composition is analyzed as x=0.25, y=1.81. Each element is evaluated for operation characteristics.

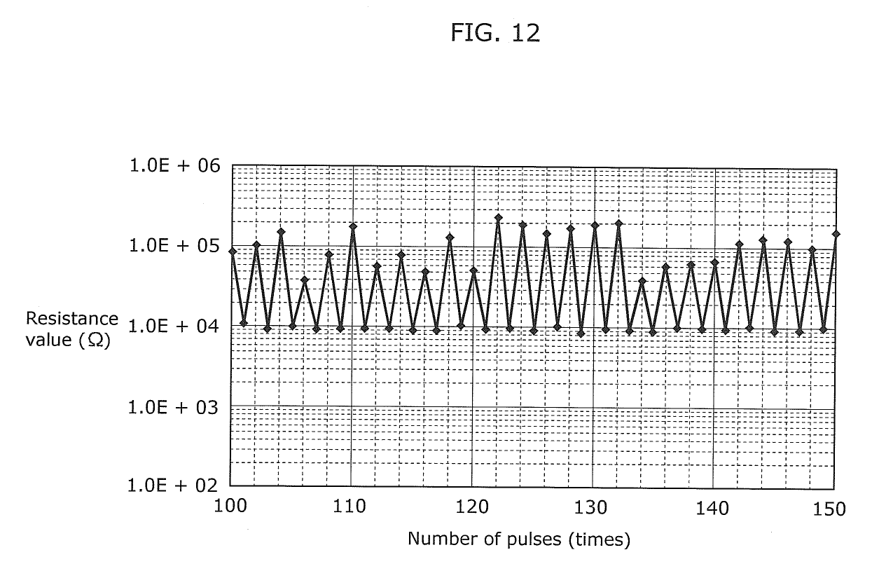

FIG. 12 is a graph showing variable resistance characteristics of the element A when pulses are applied. As shown in FIG. 12, the element A changes between a high resistance state and a low resistance state by applying two types of voltage pulses having different polarities. In other words, when a negative voltage pulse (voltage of −1.5 V, pulse width of 100 ns) is applied to the upper electrode 207 relative to the lower electrode 205, the element A changes from a high resistance state (resistance value of approximately 150000Ω) to a low resistance state (resistance value of approximately 10000Ω). In contrast, when a positive voltage pulse (voltage of 2.4 V, pulse width of 100 ns) is applied to the upper electrode, the element A increases from the low resistance state to the high resistance state.

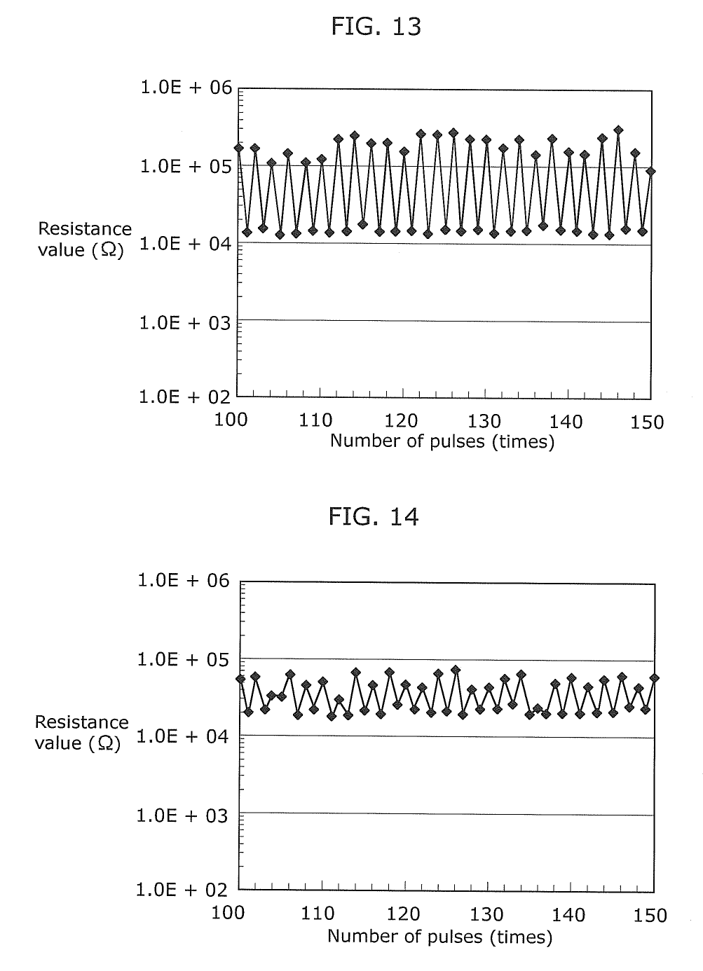

FIG. 13 and FIG. 14 are graphs showing variable resistance characteristics of the element B and the element C, respectively. The conditions of application of voltage pulses are the same as that of FIG. 12. Comparison of FIG. 13 and FIG. 14 shows that, between the element B and the element C having the tantalum oxynitride thin films formed while the substrates are kept at the same temperature of 400 degrees Celsius, variable resistance characteristics of the element C, which has higher proportion of the sum of the oxygen atoms and the nitrogen atoms in the film and has higher specific electrical resistance value, is slightly inferior (resistance ratio between the high resistance state and the low resistance state is small) to the element B that has lower specific electrical resistance value.

Here, an application of the positive voltage refers to the case where a high voltage is applied to the upper electrode 207 relative to the lower electrode 205 shown in FIG. 11, and an application of the negative voltage refers to the case where a low voltage is applied to the upper electrode 207 relative to the lower electrode 205. As described above, any of the elements can perform resistance change operation at a voltage equal to or lower than 2.4 V.

This is because a voltage pulse applied for a resistance change operation is distributed to both the tantalum oxide layer of the first variable resistance layer and the oxygen- and/or nitrogen-deficient tantalum oxynitride layer of the second variable resistance layer. The resistance change operation is caused by the voltage distributed to the tantalum oxide layer to which oxygen atoms enter and from which oxygen atoms exit. It is considered that the nonvolatile memory device can be operated at low voltage when the voltage distributed to the tantalum oxide layer increases by setting the resistivity of the tantalum oxide layer to be higher than the resistivity of the oxygen- and/or nitrogen-deficient tantalum oxide layer.

To confirm this assumption, three types of planar-type elements each having a second variable resistance layer manufactured with different methods or materials were manufactured. For each type, plurality of planar-type elements was manufactured and initial resistance values of 49 elements were measured. Medians of the measured initial resistance values are shown in Table 1.

In all types of the elements, the first variable resistance layer having a high oxygen concentration is a Ta₂O₅ film which has a thickness of 5 nm formed by the sputtering method. Furthermore, depending on the type of the elements, the second variable resistance layer comprising the oxynitride having a low oxygen concentration is one of: a TaOₓ film having a thickness of 50 nm formed by the sputtering method; a TaOₓ film having a thickness of 50 nm formed by the CVD method; and a TaOₓN_{y} film having a thickness of 50 nm formed by the CVD method.

Table 1 shows that the median of the initial resistance values increase significantly when the second variable resistance layer comprises oxynitride. With such a structure, diffusion of oxygen atoms from the first variable resistance layer to the second variable resistance layer is suppressed. This is because tantalum oxynitride is, like TaN, a stable compound having high barrier properties, and in the metal oxynitride, a portion of nitrogen atoms in the metal nitride is substituted by oxygen atoms and thus, with regard to the diffusion of oxygen atoms from the interface, there is an effect of suppressing sites where nitrogen is substituted by oxygen after diffusion. As a result, it is assumed that a resistance value of the first variable resistance does not decrease.

TABLE 1

| First variable | Second variable | Median of initial resistance |
|---|---|---|
| resistance layer | resistance layer | values (49 elements) |
| Ta₂O₅ sputtered film | Sputtering - TaOₓ film | 3.6 × 10⁶ (Ω) |
| (5 nm) | (50 nm) | |
| Ta₂O₅ sputtered film | CVD - TaOₓ film | 2.5 × 10¹⁰ (Ω) |
| (5 nm) | (50 nm) | |
| Ta₂O₅ sputtered film | CVD - TaOₓN_{y} film | 1.3 × 10¹² (Ω) |
| (5 nm) | (50 nm) | |

### Embodiment 2

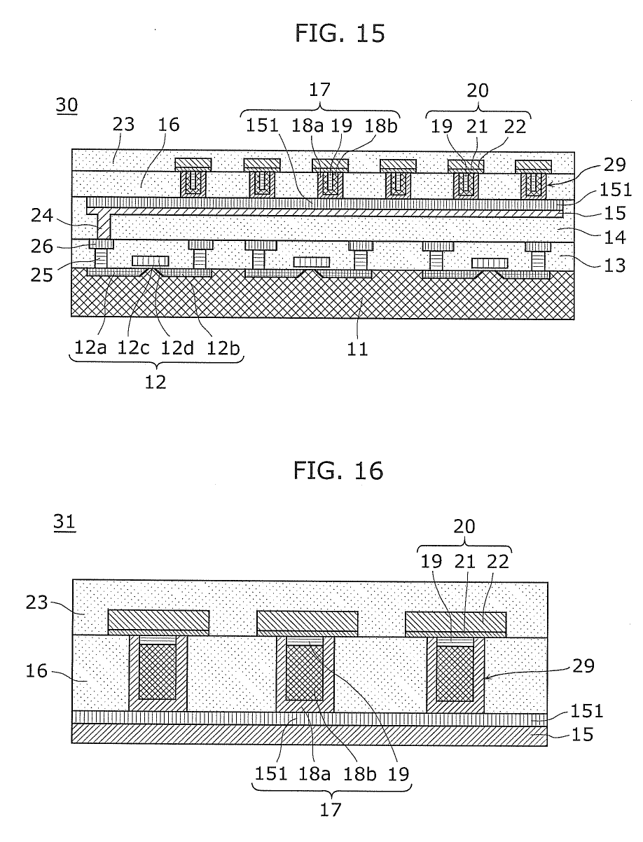

FIG. 15 is a cross-sectional view for describing a structure of a nonvolatile memory device 30 according to Embodiment 2 of the present invention. The nonvolatile memory device 30 has a structure based on the nonvolatile memory device 10 according to Embodiment 1 shown in FIG. 1 and the structure in which the variable resistance layer, which are embedded in a memory cell hole in an interlayer insulating layer, and a layer, which forms a non-ohmic element between a first electrode and a first line, are stacked. This structure makes it possible to control a sneak current from other elements, and increase the reliability of operation of the nonvolatile memory element.

The manufacturing method differs from that according to Embodiment 1 only in that a first current steering layer 21 is provided between the first electrode 19 and the first line 22 in the step described with reference to FIG. 9.

When the first current steering layer 21 is an insulator, a first non-ohmic element 20 is a metal-insulator-metal (MIM) diode. When the first current steering layer 21 is a semiconductor, the first non-ohmic element 20 is a metal-semiconductor-metal (MSM) diode.

When an insulator is used as a material of the first current steering layer 21, silicon nitride (Si₃N₄) can be used. When a semiconductor is used as a material of the first current steering layer 21, nitrogen-deficient silicon nitride which has less nitrogen content than Si₃ N₄ can be used.

The nitrogen-deficient silicon nitride film can be formed by using what is called a reactive sputtering method in which sputtering is performed on a polycrystalline silicon target in an atmosphere including a mixed gas of argon and nitrogen. The film can be formed by adopting an implementation in which a film formation time is adjusted such that the thickness of the silicon nitride film becomes 5 to 20 nm under typical conditions of film formation, that is, a pressure is set to 0.08 to 2 Pa, a substrate temperature is set to 20 to 300 degrees Celsius, a flow ratio of nitrogen gas (proportion of flow rate of nitrogen to a total flow rate of argon and nitrogen) is set to 0 to 40%, and DC power is set to 100 to 1300 W.

A work function of a tantalum nitride is 4.6 eV and is sufficiently higher than an electron affinity of silicon of 3.8 eV. Thus, when the first line 22 comprises tantalum nitride, a Schottky barrier is formed at the interface between the first current steering layer 21 and the first line 22. When both of the first line 22 and the first electrode 19 comprise tantalum nitride, the first non-ohmic element 20 serves as a bidirectional MIM diode or a bidirectional MSM diode.

In this embodiment, the first electrode 19 is completely embedded in the memory cell hole 29 (lower than the upper opening is) as shown in FIG. 15, and the surface of the first electrode 19 can be processed to be very smooth. When the first current steering layer 21 is formed on such a smooth surface, a dense and continuous layer can be obtained even when the layer is thin, and a breakdown voltage (a characteristic indicating that breakdown does not occur even upon application of a relatively high voltage) of the first current steering layer 21 can be appropriately ensured.

The first current steering layer 21 completely covers the upper surface of the first electrode 19. Thus, unlike the conventional non-ohmic element which has all the layers embedded in a memory cell hole, there is no concern for a current leakage, which occurs when the first electrode 19 contacts the first line 22 directly in a surrounding area of the first current steering layer 21 without being interposed by the first current steering layer 21.

The first line 22 is provided so as to extend beyond the perimeter of the first electrode 19 viewed from the substrate-thickness direction. Thus, a path of a current flowing in the first non-ohmic element 20 is formed to extend outward beyond the perimeter of the first electrode 19 viewed from the substrate-thickness direction.

In this case, lines of electric force due to an electric field are formed to spread horizontally, from the first electrode 19 in the memory cell hole 29, toward the first current steering layer 21. Thus, the effective area of the first non-ohmic element 20 (the MIM diode or the MSM diode) is larger than the effective area of the conventional non-ohmic element which has all the layers embedded in the memory cell hole.

Therefore, it is possible to obtain the first non-ohmic element 20 formed of the MIM diode or the MSM diode that have a greater current capacity and less variation in characteristics compared to the conventional non-ohmic element.

(Modification of Embodiment 2)

The following describes a modification of the nonvolatile memory device having the first non-ohmic element.

FIG. 16 is a cross-sectional view showing an example of a structure of main parts of a nonvolatile memory device 31 according to a modification of Embodiment 2 of the present invention. Each of the components in FIG. 16 is assigned by the same reference numeral as the reference numeral of the component having the same function in the nonvolatile memory device 30 in FIG. 15.

As shown in FIG. 16, the different point of the nonvolatile memory device 31 from the nonvolatile memory device 30 is the shapes of the second variable resistance layer 18b and the first electrode 19, and the common point is that the first electrode 19 is completely embedded in the memory cell hole 29.

The nonvolatile memory device 31 may be formed, for example, according to the following manufacturing method.

First, a structure shown in FIG. 5 or the like in which the first variable resistance material layer 181a is formed on the third interlayer insulating layer 16 and in the memory cell hole 29 is produced by performing the same steps described with reference to FIG. 3 to FIG. 5 in Embodiment 1. Next, the second variable resistance material layer 181b is formed by the CVD method so as to fill the memory cell hole 29′ in which the first variable resistance material layer 181a is formed.

Next, before forming the first electrode material layer 191, portions of the second variable resistance material layer 181b, and the first variable resistance material layer 181a (i) which cover the surface of the third interlayer insulating layer 16 and (ii) above the upper opening of the memory cell hole 29 (a portion having a height from the substrate higher than the height of the upper surface of the third interlayer insulating layer 16) are removed by the CMP process.

At this time, a portion of the upper surface of the second variable resistance material layer 181b is removed to a height lower than the upper surface of the third interlayer insulating layer 16, and a recess which is characteristic of the CMP process is formed. The first electrode material layer 191 is formed on the second variable resistance material layer 181b and the third interlayer insulating layer 16 by the CVD method so as to fill the recess. Next, by the CMP process again, portions of the first electrode material layer 191 which covers the surface of the third interlayer insulating layer 16 and above the upper opening of the memory cell hole 29 are removed.

Next, the step described with reference to FIG. 9 in Embodiment 1 is performed. Thus, the nonvolatile memory device 31 is completed.

In the nonvolatile memory device 31 too, in the same manner as the nonvolatile memory device 30, the first electrode 19 is completely embedded in the memory cell hole 29, and the first line 22 is provided so as to extend beyond the perimeter of the first electrode 19 viewed from the substrate-thickness direction. Thus, it is possible to obtain the first non-ohmic element 20 that has no concern for a current leakage due to the direct contact between the first electrode 19 and the first line 22 and has a larger effective area compared to the conventional non-ohmic element in which all the layers are embedded in the memory cell hole.

### Embodiment 3

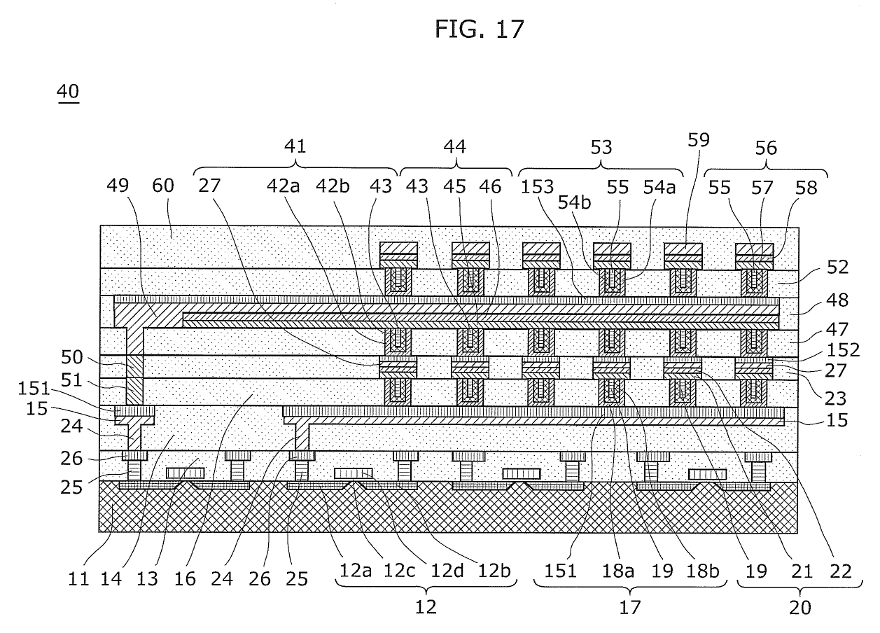

FIG. 17 is a cross-sectional view for describing a structure of a nonvolatile memory device 40 according to Embodiment 3 of the present invention. The basic structure of the nonvolatile memory device 40 is the memory cell array of the nonvolatile memory device 30 according to Embodiment 2 shown in FIG. 15, and the basic structures each of which is a structural unit are stacked to form a multilayered memory cell array. By stacking the memory cell arrays as described above, it is possible to implement a nonvolatile memory device having a larger capacity.

The nonvolatile memory device 40 is an example of a structure in which three stages of the variable resistance elements and three stages of the non-ohmic elements are stacked. To facilitate the understanding of and differentiate the structural requirements of memory cell array of each of the first, second, and third stages, the term “first-stage” is added to the structural requirements of the first stage, the term “second-stage” is added to the structural requirements of the second stage, and the term “third-stage” is added to the structural requirements of the third stage. In the following, the components same as the components included in the nonvolatile memory device 30 are denoted by the same reference numerals, and descriptions thereof are omitted as appropriate.

The following briefly describes a structure of the nonvolatile memory device 40 according to this embodiment. Note that in the nonvolatile memory device 30 shown in FIG. 15, the first lines 22 are formed so as to extend beyond the region in which the first variable resistance elements 17 and the first non-ohmic elements 20 are formed in a matrix.

On the other hand, in the nonvolatile memory device 40 according to this embodiment, second linings 27 and second electrode lines 152 that are components different from the first lines 22 are provided so as to extend on the first lines 22 in the matrix region as well. Furthermore, such structure is provided in the second stage and the third stage as well.

Furthermore, when the first-stage first lines 22 and the second-stage second linings 27 comprise the same material, one common line layer may be shared by the first stage and the second stage. Further, such sharing is also possible between the second stage and the third stage.

Further, a fifth interlayer insulating layer 47 is formed on the fourth interlayer insulating layer 23 that includes the second linings 27 and the second electrode lines 152. In the fifth interlayer insulating layer 47, a memory cell hole is provided in a position corresponding to each of the first variable resistance elements 17. A third variable resistance layer 42a, a fourth variable resistance layer 42b, and a second electrode 43 that make up second-stage variable resistance layer are embedded in the memory cell hole.

Furthermore, a second current steering layer 45, a second-stage second line 46, a third lining 49 and a third electrode line 153 that are connected to the second electrode 43 are formed in a strip shape in a direction crossing the second lining 27 viewed from the substrate-thickness direction. Further, a sixth interlayer insulating layer 48 is formed to embed the second current steering layer 45, the second-stage second line 46, the third lining 49 and the third electrode line 153.

A seventh interlayer insulating layer 52 is formed on the third electrode line 153 and the sixth interlayer insulating layer 48. In the seventh interlayer insulating layer 52, a memory cell hole is provided in a position corresponding to the first variable resistance element 17 (first-stage memory unit) and second variable resistance element 41 (second-stage memory unit). A fifth variable resistance layer 54a, a sixth variable resistance layer 54b, and a third electrode 55 that make up a third-stage variable resistance layer are embedded in the memory cell hole.

Furthermore, a third current steering layer 57, a third line 58, and a fourth lining 59 connected to the third electrode 55 are formed in a strip shape in a direction crossing the third lining 49 and the third electrode line 153 viewed from the substrate-thickness direction. Further, an eighth interlayer insulating layer 60 is formed to embed and protect the third current steering layer 57, the third line 58, and the fourth lining 59.

Note that the second variable resistance element 41 (a second-stage memory unit) includes: the second-stage variable resistance layer (formed of the third variable resistance layer 42a and the fourth variable resistance layer 42b); and the second electrode line 152 and the second electrode 43 in regions between which the second-stage variable resistance layer is interposed. Furthermore, the second electrode 43, the second current steering layer 45, and the second line 46 make up a second non-ohmic element 44.

Further, a third variable resistance element 53 (a third-stage memory unit) includes: a third-stage variable resistance layer (formed of the fifth variable resistance layer 54a and the sixth variable resistance layer 54b); and the third electrode line 153 and the third electrode 55 in regions between which the third-stage variable resistance layer is interposed. Furthermore, the third electrode 55, the third current steering layer 57, and the third line 58 make up a third non-ohmic element 56.

Furthermore, the first lining 15 is connected to the source region 12a of the active element 12 through the second embedded conductor 24, the first embedded conductor 25, and the circuit line 26. Furthermore, in the same manner, the second lining 27 is also connected to an active element (not shown) through embedded conductors (not shown) and a circuit line (not shown).

Further, as shown in FIG. 17, the third lining 49 is connected to the source region 12a of another active element 12 through a fifth embedded conductor 50, a fourth embedded conductor 51, the first electrode line 151, the first lining 15, the second embedded conductor 24, the circuit line 26, and the first embedded conductor 25. Furthermore, in the same manner as the second lining 27, the fourth lining 59 is also connected to yet another active element through other embedded conductors (not shown) and another circuit line (not shown).

The first-stage first lining 15 and the first-stage second lining 27 are one of a bit line and a word line, respectively, and connected to, for example, a bit line decoder and a word line decoder, respectively, that are used in a general memory drive circuit. Furthermore, the second lining 27 and the third lining 49 are, in the same manner, one of a bit line and a word line, respectively, and connected to the bit line decoder and the word line decoder, respectively.

However, when the second lining 27 forms the bit line in the first stage, it is designed such that the bit line is formed in the second stage as well and the third lining 49 forms the word line. Further, when the third lining 49 forms the word line, it is designed such that the fourth lining 59 forms the bit line.

As described above, in the nonvolatile memory device 40 according to this embodiment, for the first variable resistance element 17, the second variable resistance element 41, and the third variable resistance element 53 that are provided in a corresponding one of the stages (corresponding one of the layers of the multilayer memory cell array), the first non-ohmic element 20, the second non-ohmic element 44, and the third non-ohmic element 56 are separately provided, respectively. Thus, it is possible to stably and reliably perform writing and reading of the first variable resistance element 17, the second variable resistance element 41, and the third variable resistance element 53 that are provided in the respective stages.

In the manufacturing steps of the nonvolatile memory device 40 having a multistage structure memory units and non-ohmic elements, it is basically only necessary to repeat the steps included in the manufacturing method of the nonvolatile memory device 30 according to Embodiment 2.

Note that the basic structure of the nonvolatile memory device according to the above-described Embodiment 3 is the memory cell array of the nonvolatile memory device 30 according to Embodiment 2 shown in FIG. 15, and the basic structures each of which is a structural unit are stacked to form a multilayered memory cell array. However, instead of the structure shown in FIG. 15, the memory cell array of the nonvolatile memory device 31 according to modification of Embodiment 2 shown in FIG. 16 can also be used as the basic structure, and the basic structures each of which is a structural unit can be stacked to form a multilayered memory cell array. This structure can also provide the same advantageous effects as Embodiment 3.

### Industrial Applicability

The nonvolatile memory device according to an implementation of the present invention includes in a hole two variable resistance layers having different oxygen content atomic percentages, and one of the two variable resistance layers (i) has an oxygen concentration lower than an oxygen concentration of the other of the two variable resistance layers, and (ii) comprises an oxygen- and/or nitrogen-deficient metal oxynitride. With this, a diffusion of oxygen atoms between the variable resistance layers can be reduced, and thus, the nonvolatile memory device according to an implementation of the present invention is useful in a variety of electronic device fields.

### REFERENCE SIGNS LIST

10, 30, 40 Nonvolatile memory device (ReRAM)
11 Substrate
12 Active element
12a Source region
12b Drain region
12c Gate insulating film
12d Gate electrode
13 First interlayer insulating layer
14 Second interlayer insulating layer
15 First lining
16 Third interlayer insulating layer
17 First variable resistance element
18a First variable resistance layer
18b Second variable resistance layer
19 First electrode
20 First non-ohmic element
21 First current steering layer
22 First line
23 Fourth interlayer insulating layer
24 Second embedded conductor
25 First embedded conductor
26 Circuit line
27 Second lining
28 Third embedded conductor
29 Memory cell hole
41 Second variable resistance element
42a Third variable resistance layer
42b Fourth variable resistance layer
43 Second electrode
44 Second non-ohmic element
45 Second current steering layer
46 Second line
47 Fifth interlayer insulating layer
48 Sixth interlayer insulating layer
49 Third lining
50 Fifth embedded conductor
51 Fourth embedded conductor
52 Seventh interlayer insulating layer
53 Third variable resistance element
54a Fifth variable resistance layer
54b Sixth variable resistance layer
55 Third electrode
56 Third non-ohmic element
57 Third current steering layer
58 Third line
59 Fourth lining
60 Eighth interlayer insulating layer
151 First electrode line
152 Second electrode line
153 Third electrode line
181a First variable resistance material layer (first deposited film)
181b Second variable resistance material layer (second deposited film)
191 First electrode material layer
200 Substrate
201, 211 Line
204, 210 Contact plug
205 Lower electrode
206 Variable resistance layer
206a First variable resistance layer
206b Second variable resistance layer
207 Upper electrode

1. A nonvolatile memory device comprising:
first electrode lines each of which is formed in a strip shape above a substrate;
an interlayer insulating layer formed on said first electrode line and above said substrate;
a memory cell hole which penetrates through said interlayer insulating layer to reach said first electrode line;
a variable resistance layer formed in said memory cell hole so as to cover a bottom and a side face of said memory cell hole;
a first electrode formed on said variable resistance layer in said memory cell hole; and
first lines each of which is formed above said first electrode and said interlayer insulating layer so as to cover at least an opening of said memory cell hole, said first line being formed in a strip shape in a direction crossing said first electrode line,
wherein said variable resistance layer has a stacked structure including (i) a first variable resistance layer comprising an oxygen-deficient transition metal oxide and (ii) a second variable resistance layer comprising an oxygen- and/or nitrogen-deficient transition metal oxynitride having an oxygen content atomic percentage different from an oxygen content atomic percentage of said first variable resistance layer, and
z>(x+y)
is satisfied when the transition metal is represented by M, a composition of said first variable resistance layer is represented by MO_{z}, and a composition of said second variable resistance layer is represented by MOₓN_{y}.

2. The nonvolatile memory device according to claim 1,
wherein said first variable resistance layer is in contact with the bottom and the side face of said memory cell hole, and said second variable resistance layer is in contact with said first variable resistance layer.

3. The nonvolatile memory device according to claim 1,
wherein the transition metal is a transition metal selected from the group consisting of tantalum, hafnium, zirconium, nickel, and titanium.

4. The nonvolatile memory device according to claim 1,
wherein the transition metal is tantalum.

5. The nonvolatile memory device according to claim 4,
wherein a sum of the number of oxygen atoms and the number of nitrogen atoms in an oxygen- and/or nitrogen-deficient tantalum oxynitride is 50 to 70 atm %.

6. The nonvolatile memory device according to claim 1, further comprising
a first current steering layer disposed between said first electrode and said first line.
